(19) United States
(12) Patent Application Publication
(10) Pub. No.: US 2008/0284860 A1
(43) Pub. Date: Nov. 20, 2008

(54) Image stabilization driving device

(75) Inventors: Wen-I Wu, Hsinchu (TW); Chao-Chang Hu, Hsinchu (TW); Tzong-Che Ho, Hsinchu (TW); Ming-Jye Tsai, Hsinchu (TW); Sheng-Chih Shen, Hsinchu (TW)

Correspondence Address: BIRCH STEWART KOLASCH & BIRCH, PO BOX 747, FALLS CHURCH, VA, 22040-0747, US

(73) Assignee: Industrial Technology Research Institute, Hsinchu Hsien (TW)

(21) Appl. No.: 11/976,610

(22) Filed: Oct. 25, 2007

(30) Foreign Application Priority Data
May 17, 2007 (TW) 096117525

(51) Int. Cl. H04N 5/225; H03H 9/25

(52) U.S. Cl. 348/208.7; 310/313 R; 348/E05.046

(57) ABSTRACT

An image-stabilizing driving device is proposed, including a slidable block coupled to an image sensor, a flat surface acoustic wave actuator for contacting with and driving the slidable block to move on a surface contacted therewith, and a contactless force action unit having a first and a second contactless force action layers. The first contactless force action layer is formed between the slidable block and the image sensor and the second contactless force action layer is formed on a bottom surface of the flat surface acoustic wave actuator, thereby providing preload force for the slidable block to contact with flat surface ascoustic wave actuator so as to form a thin image-stabilizing driving device.

### FIELD OF THE INVENTION

The present invention relates to a driving device, and more particularly to an image stabilization driving device for preventing image quality deterioration caused by shaking.

### BACKGROUND OF THE INVENTION

Nowadays, due to the thickness limitation of the optical system concerned by mobile phone or camera, the structures of the optical system and the actuator are as simple as possible, and their sizes are as small as possible, so as to adapt these devices to the development trend of miniaturization or thin profile.

A piezoelectric actuator has the advantages of small size, large output, low power consumption, silence and high compatibility, and thus is adopted by a digital camera or a camera phone to drive an optical lens therein, such that the optical lens functions to zoom in or zoom out, making it one of the critical techniques of optical systems or related products. Meanwhile, while camera phone is gradually replacing digital camera, user's demand for the quality of camera phone is also increasingly growing. Whereas, in view of the trend of miniaturization, camera phone is prone to the impact of external vibration, especially the one caused by hands, while taking a picture. Such impact will introduce a bad quality of image taken, which makes the image blurry and unrecognizable. Therefore, an image stabilization device is brought into play to prevent the impact of external vibration on image quality.

For the cameras disclosed in a US patent (Patent No.: US20030067544) and Japan patents (Patent No.: JP200311144 and JP2004241922) to stabilize image-capturing quality by a compensation design, WADA et al. (Minolta Co. (JAPAN), LTD.) disclose a design that integrates a Smooth Impact Drive Mechanism (SIDM) in a lens module and employs two sets of piezoelectric actuators to control the coordinates (X, Y) of an image sensor on a mounting plane, so as to achieve the image stabilization function. The SIDM disclosed by those prior arts is formed by stacking three layers of metal frames together. However, from the design point of view, the mechanism still needs to be assembled from parts, and its assembly process and parts are diverse and complicated, so as to fail to meet the miniaturization requirement of modules. As such, the existing image stabilization techniques all position digital camera as their product market focus just because the size and complexity of mechanism in those techniques all fail to keep abreast with the miniaturization trend of camera phone.

A lens actuator using surface acoustic wave (SAW) linear motor, which is disclosed in a US patent (Patent No.: US20060170307), is employed to focus or zoom. The SAW linear motor includes a SAW component integrated in an enclosure for lens, a slidable block driven through the SAW component and coupled to the lens. The SAW component is one having two sets of Inter-digital Transducers (IDT) designed on a piezoelectric substrate with a smooth surface, in which one set of IDT serves to input and generate surface stationary waves on the piezoelectric substrate by processing the received electrical signals with the converse piezoelectric effect; the surface stationary waves pass through a delay line zone between the two sets of IDTs to reach the other set of IDT serving to output and convert the received SAW into electrical signal with the direct piezoelectric effect. If observing any point on the piezoelectric substrate, an elliptical motion trajectory is shown. By means of frequency accumulation, such infinitesimal displacing effect can result in a shifting effect, which is applied to a linear motor in the prior art.

Although the SAW linear motor constituted by integrating the SAW component with the slidable block is already disclosed in the prior art and the SAW linear motor is applied to focus or zoom the lens, in spite of the advantage in favor of miniaturization or thin profile, the prior art has no mentioning of any application pertinent to image stabilization. Besides, the aforementioned SAW linear motor shall be integrated in the enclosure for lens to provide the preload force for driving the slidable block to contact with the SAW component by pressing the enclosure. Such design for controlling the preload force extremely requires matching accuracy, not only giving rise to the difficult), in production and assembly but also easily resulting in the driving uncertainty, which seriously deteriorates the driving accuracy.

Owing to the foregoing shortcoming of the prior art, how to provide an image stabilization driving device for realizing thin profile, simple parts, easy production and assembly and so forth, and further tackle the issue intrinsic to the above-mentioned conventional structure becomes a topics on top of the list required to be overcome in no time by the industry.

### SUMMARY OF THE INVENTION

In view of the shortcoming of the prior art, in accordance with a first object of the present invention, a thin image stabilization device is provided.

In accordance with a second object of the present invention, an image stabilization device with simple parts is provided.

In accordance with a third object of the present invention, an image stabilization device that is easily produced and assembled is provided.

To achieve the above-mentioned objects and other objects, the present invention provides an image stabilization driving device for driving two-dimensional displacement of an image sensor, which includes a slidable block for being integrated with the image sensor, a flat SAW actuator that carries and contacts with the slidable block and drives the slidable block to move on a surface contacted therewith, and an contactless force action unit containing a first contactless force action layer formed between the slidable block and the image sensor and a second contactless force action layer formed on the flat SAW actuator and providing a preload force for the slidable block to contact with the flat SAW actuator by means of a mutually attracting force at a distance between the first and second contactless force action layers.

In the aforementioned image stabilization driving device, the slidable block is contacted with a surface of the flat SAW actuator having a plurality of contact dots to reduce the surface friction, in which the plural contact dots are aligned in form of a matrix. Moreover, the image stabilization driving device further includes a position sensor to sense a planar moving position of the slidable block for the purpose of feedback control. The flat SAW actuator includes a piezoelectric substrate, and two pairs of IDTs that are mutually orthogonal and are formed on a surface of the piezoelectric substrate. The slidable block is driven with the converse piezoelectric effect acted on the piezoelectric substrate by the two pairs of IDTs to have a planar movement.

The contactless force action unit varies with different preferred embodiment based on magnetic force or electrostatic force. In a first preferred embodiment, the first contactless force action layer could be a permeable layer and the second contactless force action layer could be a permanent-magnet layer, in which the permanent-magnet layer could be a permanent-magnet substrate attached on the bottom surface of the flat SAW actuator while there is no definite limitation therefor. In a second preferred embodiment, the first contactless force action layer could be a first polar electrode layer and the second contactless force action layer could be a polar electrode layer having the polarity different from that of the first polar electrode layer with the first polarity, in which the first polar electrode layer and the second electrode layer are a positive electrode layer and a negative electrode layer of different polarity respectively, and the mounting positions corresponding to the positive and negative electrode layers could be altered based on actual implementation while they are not subjected to any specific limitation.

To achieve the same object, the present invention further provides an image stabilization device for driving a planar movement of the image sensor, which includes a first slidable block coupled to the image sensor; a first linear SAW actuator carrying and contacting with the first slidable block to drive a linear movement of the first slidable block on a surface contacted therewith; a second slidable block coupled to a bottom surface of the first linear SAW actuator; a second linear SAW actuator being orthogonal to the first linear SAW actuator and carrying and contacting with the second slidable block to drive a linear movement of the second slidable block on a surface contacted therewith; and an contactless force action unit containing a first force-at-a-distance active layer formed between the first slidable block and the image sensor and between the second slidable block and the first linear SAW actuator respectively, and a second contactless force action layer formed on the bottom surface of the second linear SAW actuator, so as to provide a preload force for the first and second slidable blocks to contact with the first and second linear SAW actuators by virtue of a mutually attracting force at a distance between the first and second contactless force action layers.

The surface of the first slidable block contacted with the first linear SAW actuator has a plurality of contact dots, and similarly, the surface of the second slidable block contacted with the second linear SAW actuator also has a plurality of contact dots, for the purpose of reducing the surface friction, in which the plural contact dots are aligned in form of a matrix; the first and second linear SAW actuators contain a piezoelectric substrate and two pairs of IDTs formed respectively on the piezoelectric substrate and aligned orthogonally, such that the two pairs of IDTs act on the piezoelectric substrate with the converse piezoelectric substrate to drive a linear movement of the first slidable block with respect to the second linear SAW actuator.

The contactless force action unit could vary with different preferred embodiment classified in accordance with magnetic force or electrostatic force. In the first preferred embodiment, the first contactless force action layer could be a permeable layer and the second action-at-a-distance acting layer could be a permanent-magnet layer, in which the permanent-magnet layer could be a permanent-magnet substrate bonded to the bottom surface of the second SAW actuator while there is no definite rule for it. In the second preferred embodiment, the first contactless force action layer could be a first polar electrode layer and the second contactless force action layer could be a second polar electrode layer with different polarity, in which the first polar electrode layer and the second polar electrode layer could be a positive electrode layer and a negative electrode layer of different polarities, and the mounting positions corresponding to the positive and negative electrodes could be altered based on actual implementation and are not subjected to any specific limitation.

As the image stabilization driving device provided by the present invention employs the SAW actuator and the contactless force action unit to integrate with and drive the slidable block. In contrast to the complicated structure and size in the prior art incorporating with a multi-layer metal frame and a piezoelectric actuator, the present invention certainly achieves the object of thin profile and simple parts and also facilitates its application to electronic devices, e.g. mobile phone. Besides, the slidable block, the SAW actuator and the contactless force action unit of the present invention have no complicated design and thus could be produced with parts of regular specification or integrally formed, thereby achieving the object of easy assembly and manufacture as well and overcoming the drawback of the prior art relatively.

### BRIEF DESCRIPTION OF THE DRAWINGS

FIG. 1 is a structural schematic view showing a first preferred embodiment for the image stabilization driving device of the present invention;

FIG. 2 is a side view of FIG. 1;

FIG. 3 is a schematic view showing a preferred embodiment of an position sensor integrated in the image stabilization driving device of the present invention;

FIG. 4 is a side view of FIG. 3;

FIG. 5 is a structural schematic view showing a second preferred embodiment for the image stabilization driving device of the present invention; and

FIG. 6 is a side view of FIG. 5.

### DETAILED DESCRIPTION OF THE PREFERRED EMBODIMENT

Together with illustrative description, preferred embodiments of the present invention are provided as follows to make one ordinarily skilled in the related art easily understand the technical features and achieved efficacy of the present invention.

### First Preferred Embodiment

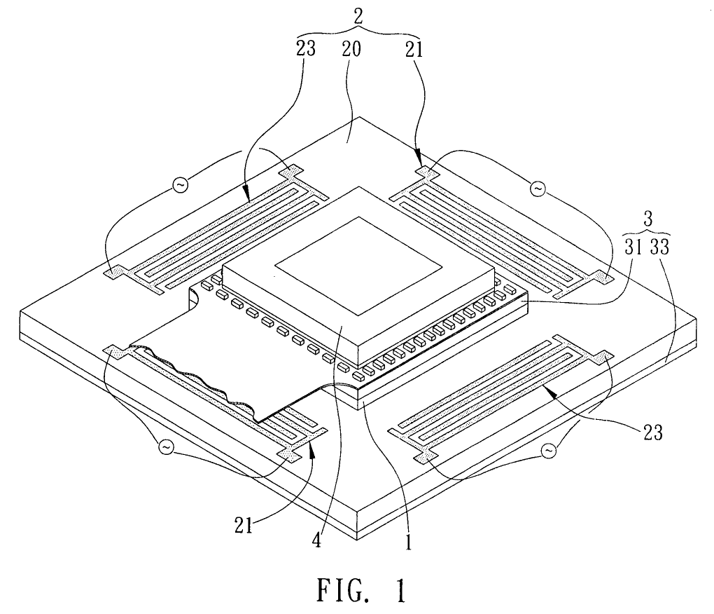

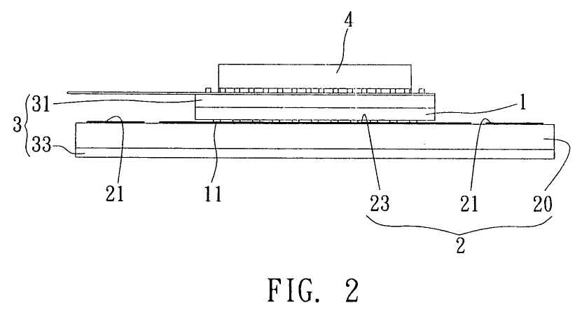

As shown in FIG. 1 and FIG. 2 illustrating the first preferred embodiment for the image stabilization driving device of the present invention, the image stabilization driving device serves to drive a planar movement of an image sensor 4. The image stabilization driving device includes a slidable block 1 coupled to the image sensor 4, a flat SAW actuator 2 driving the slidable block 1 to have a planar movement on a surface contacted therewith, and an contactless force action unit 3 providing a preload force for the slidable block 1 to contact with the flat SAW actuator 2, thereby achieving the object of thin profile and simple parts for the image stabilization driving device and overcoming the shortcoming of the prior art failing to attain thin profile and simple parts.

The slidable block 1 pertains to a flat-panel design, where its top side is integrated with the image sensor 4 of an optical system which is usually a CCD (Charge Coupled Device) or a CMOS while there is no definite rule for it. The size of the slidable block 1 is about that of the image sensor 4; however, it shall be large enough to be integrated with the image sensor 4; other than that, there is no definite limitation. In the present preferred embodiment, a surface of the slidable block 1 contacted with the flat SAW actuator 2 (bottom side up in FIG. 1) has a plurality of contact dots 11 for the purpose of reducing surface friction. The plural contact dots 11 could be aligned in form of a matrix to make them co-planar. Despite the plural contact dots 11 in the present embodiment serving to reduce surface friction, the presence of the contact dots may not be a must. For example, a plurality of grooves or troughs formed on the bottom side of the slidable block 1 could also attain the identical effect. Hence, the present invention is not limited to the disclosed embodiment.

The flat SAW actuator 2 carries and contacts with the slidable block 1 to drive the slidable block 1 so as to have a planar movement on a surface contacted therewith; in other words, the slidable block 1 is enabled to have a planar movement by commonly contacting the plural contact dots 11 on the bottom surface of the slidable block 1 with the top surface of the flat SAW actuator 2 and by driving with the flat SAW actuator 2. In the present embodiment, the flat SAW actuator 2 includes a piezoelectric substrate 20 and two pairs of IDTs 21, 23 being mutually orthogonal and formed on a surface of the piezoelectric substrate 20. Planar movement of the slidable block 1 is driven by the two pairs of IDTs 21, 23 with the converse piezoelectric effect acted on the piezoelectric substrate 20, in which one pair of IDT 21 is used to drive the slidable block 1 to have a linear movement to the right and left, and the other pair of IDT 23 is used to drive the slidable block 1 to have a linear motion to the front and back, thereby constituting a two-dimensional driving effect.

Certainly, the flat SAW actuator 2 can be applied with a single-phase resonant frequency (single frequency and single phase) or a dual-phase resonant frequency (single frequency and different phase) to drive. Whereas, depending on the applied product design, the voltage supply method utilizes connection wire or external pin. As the driving means and the connection wire or external pin pertain to the portion easily understood and accomplished by one ordinarily skilled in the related art, it is unnecessary for them to be disclosed in the present embodiment.

The contactless force action unit 3 includes a first contactless force action layer 31 formed between the slidable block 1 and the image sensor 4, and a second contactless force action layer 33 formed on a bottom surface of the flat SAW actuator 2, so as to provide a preload force for the slidable block 1 to contact with the flat SAW actuator 2 by virtue of a mutually attracting force-at-a-distance between the first contactless force action layer 31 and the second contactless force action layer 33. In the present embodiment, the first contactless force action layer 31 is a permeable layer, and the second contactless force action layer 33 is a permanent-magnet layer, for example, a permanent-magnet substrate bonded to the bottom surface of the flat SAW actuator 2, while it is not subjected to any limitation. Therefore, the normal force for surface friction that keeps slidable block 1 in contact with the surface of the flat SAW actuator 2 is rendered by the magnetic attraction.

Despite the example in the present embodiment using the magnetic attraction to describe features and mounting positions of the first contactless force action layer 31 and the second contactless force action layer 33, the mounting positions of the first contactless force action layer 31 and the second contactless force action layer 33 could be also changed by one ordinarily skilled in the related art in response to actual requirement for manufacturing the product, and are not limited to the present embodiment using magnetic attraction only. Moreover, as gravity, electrostatic force and the foregoing magnetic force all pertain to a force at a distance. As such, the contactless force action unit 3 mentioned in the present invention is absolutely not limited to the present embodiment using magnetic attraction. In other embodiments, the first contactless force action layer 31 and the second contactless force action layer 33 could be a first polar electrode layer and a second polar electrode layer with different polarity from that of the first polar electrode layer, for example, a positive electrode layer and a negative electrode layer with opposite polarities, and the mounting positions corresponding to the positive electrode layer and the negative electrode layer could be changed based on actual requirement to similarly achieve the effect using the attraction of force at a distance to confine the slidable block 1 and secure that the slidable block 1 is effectively contacted with the Rat SAW actuator 2. Because the physical structure employing positive and negative electrode layer to provide electrostatic power is the same as the illustrated structure plotted in FIG. 1 and FIG. 2, no further drawing is provided to illustrate such variation.

As the image stabilization device provided by the present embodiment employs the flat SAW actuator 2 and the contactless force action unit 3 that are integrated with and drive the slidable block 1, in contrast to the conventional technique having a complicated structure, incorporating a multi-layer metal frame with a piezoelectric actuator, and a larger size, the object of thin profile and simple parts is achievable and facilitates the application to electronic devices, e.g. mobile phone. In addition, the slidable block 1, the flat SAW actuator 2 and the contactless force action unit 3 have no complicated design and could be assembled with parts having regular specification or integrally formed, and thus the object of easy manufacture and assembly could be also achieved, thereby thoroughly overcoming the drawback of the prior art.

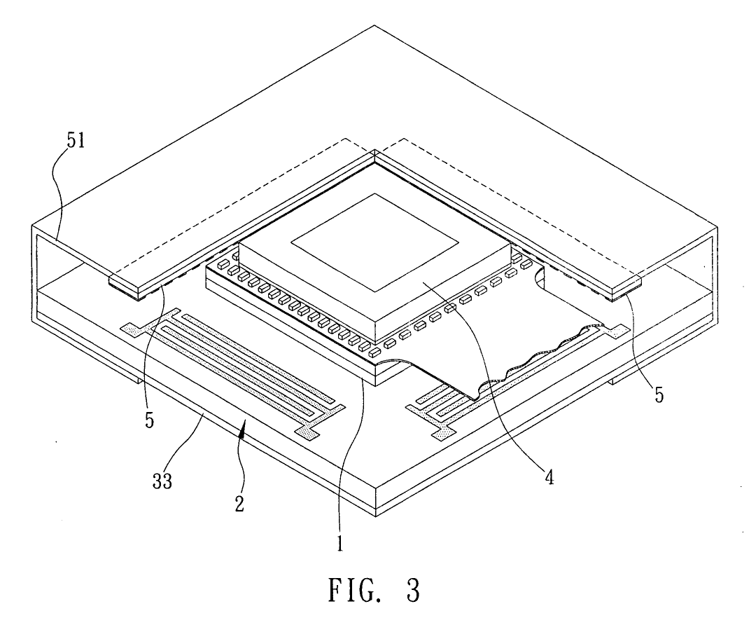

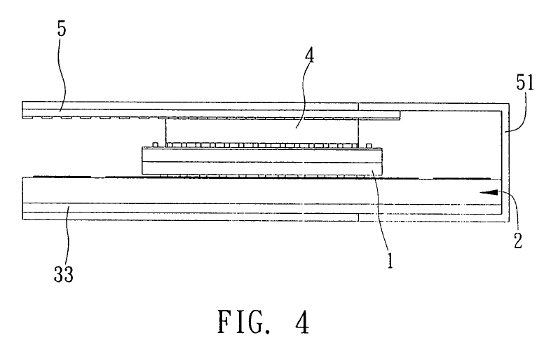

Furthermore, the image stabilization driving device provided by the present invention could increase the number of the position sensor 4, as shown in FIG. 3 and FIG. 4, for sensing a planar movement of the slidable block 1 (equivalent to sensing the image sensor 4) based on actual application to fulfill the purpose of feedback control. The position sensor could be selected from, for example, a magnetic sensor, a capacitive sensor or an optical sensor. In the present embodiment, an external frame 51 is disposed to partially cover two neighboring sides of the flat SAW actuator 2, and two neighboring sides and a bottom portion of the second contactless force action layer 33, and the position sensor 5 is disposed on two neighboring side edges of the external frame 52 corresponding to the moving direction of the image sensor 4 (equivalent to the slidable block 1), so as to provide a feedback control over the moving positions detected by the image sensor. However, one ordinarily skilled in the related art shall know that the image sensor 5 could be integrated at an adequate position of the optical system, and is not definitely limited to that integrated in the image stabilization driving device of the present embodiment.

### Second Preferred Embodiment

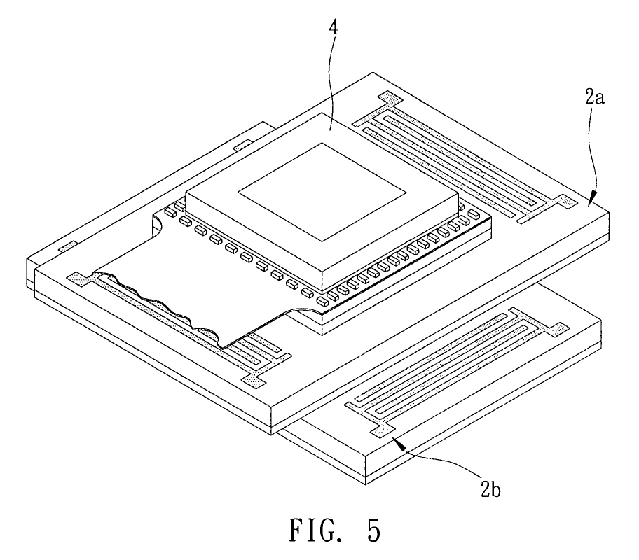

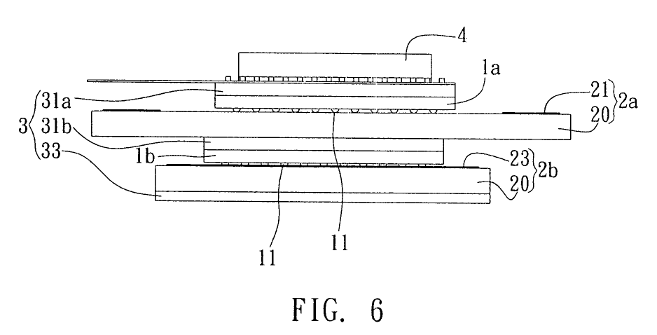

FIG. 5 and FIG. 6 are provided in accordance with the second preferred embodiment, in which components that are identical or similar to those in the aforementioned embodiment are expressed by identical or similar component symbols, and detailed description therefore is omitted to make the description of the present invention more clear and comprehensive. What the second preferred embodiment differs from the first preferred embodiment lies in that a flat SAW actuator in the first preferred embodiment and two orthogonal linear SAW actuators in the second preferred embodiment are adopted.

As shown in FIG. 5 and FIG. 6, the image stabilization driving device provided by the present embodiment includes a first slidable block la coupled to the image sensor 4; a first linear SAW actuator 2a carrying and contacting with the first slidable block 1a to drive a linear movement of the first slidable block la on a surface contacted therewith; a second slidable block 1b coupled to a bottom surface of the first linear SAW actuator 2a;

12 a second linear SAW actuator 2b carrying and contacting with the second slidable block 1b in a direction orthogonal to the first linear SAW actuator 2a to drive a linear movement of the second slidable block 1b on a surface contacted therewith; and a contactless force action unit 3 containing two first contactless force action layers 31a, 31b formed between the first slidable block la and the image sensor 4 and between the second slidable block 1b and the first flat SAW actuator 2a respectively, and a second contactless force action layer 33 formed on the bottom surface of the second linear SAW actuator 2b, so as to provide a preload force for the first slidable block 1a and the second slidable block 1b to contact with the first linear SAW actuator 2a and the second linear SAW actuator 2a by virtue of a mutually attracting force at a distance between the first contactless force action layers 31a, 31b and the second contactless force action layer 33.

A surface of the first slidable block 1a in the present embodiment contacted with the first linear SAW actuator 2a has a plurality of contact dots 11 aligned in form of a matrix, and similarly, a surface of the second slidable block 1b in the present embodiment contacted with the second linear SAW actuator 2b has a plurality of contact dots 11 aligned in form of a matrix, for the purpose of reducing surface friction. However, the contact dots and the design thereof may not be the only choice. The first linear SAW actuator 2a and the second linear SAW actuator 2b includes a piezoelectric substrate 20, and a pair of IDTs 21, 23 formed on a surface of the piezoelectric substrate 20 respectively. The two IDTs 21, 23 that are aligned orthogonally act on the piezoelectric substrate 20 with the converse piezoelectric effect to drive a planar movement of the first slidable block 1a with respect to the second linear SAW actuator 2b.

The contactless force action unit 3 could vary with different implementation in accordance with magnetic force or electrostatic force. For example, the first contactless force action layers 31a and 31b could be a permeable layer and the second contactless force action layer 33 could be a permanent-magnet layer; alternatively, for example, the first contactless force action layers 31a and 31b and the second contactless force action layer 33 could be a first polar electrode layer and a second polar electrode layer with a different polarity from that of the first polar electrode layer respectively, being, for example, a positive electrode layer and a negative electrode layer respectively, and the mounting positions of the positive and negative electrode layers could be changed based on actual implementation and are free of any specific limitation.

Besides, the design for integrating the position sensor could be applied to the present embodiment. As its physical structure is the same as that in the first embodiment, no further illustrative drawing is provided to repeatedly describe such variation.

In sum, as the image stabilization driving device provided by the present invention employs the flat SAW actuator and the contactless force action unit to be integrated with and drive the slidable block, in contrast to the complicated structure in the prior art bundling multi-layer metal frame and the piezoelectric actuator and the size, the object for securing a thin profile and simple parts is achieved by the present invention, thereby facilitating its application to electronic device, e.g. mobile phone. Moreover, the slidable block, the flat SAW actuator and the contactless force action unit of the present invention have no sophisticated design and could be assembled with parts of regular specification or integrally formed to also achieve the object of easy assembly and manufacture. Consequently, the shortcoming of the prior art is overcome, and from the above-mentioned characteristics those features of the present invention not only have a novelty among similar products and a progressiveness but also have an industry utility.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims, which are to be accorded with the broadest interpretation so as to encompass all such modifications and similar structures.

What is claimed is:

1. An image stabilization driving device for driving a planar movement of an image sensor, comprising:
a slidable block coupled to said image sensor;
a flat SAW actuator carrying and contacting with said slidable block to drive a planar movement of said slidable block on a surface contacted therewith; and
an contactless force action unit having a first contactless force action layer formed between said slidable block and said image sensor, a second contactless force action layer formed on a bottom surface of said flat SAW actuator, so as to provide a preload force for said slidable block to contact with said flat SAW actuator by a mutually attracting force-at-a-distance between said first and second contactless force action layers.

2. The image stabilization driving device of claim 1, wherein a surface of said slidable block contacted with said flat SAW actuator has a plurality of contact dots to reduce surface friction thereon.

3. The image stabilization driving device of claim 2, wherein said plural contact dots are aligned in form of a matrix.

4. The image stabilization driving device of claim 1, wherein said first contactless force action layer is a permeable layer, and said second contactless force action layer is a permanent-magnet layer.

5. The image stabilization driving device of claim 4, wherein said permanent-magnet layer is a permanent-magnet substrate bonded to said bottom surface of said flat SAW actuator.

6. The image stabilization driving device of claim 1, wherein said first contactless force action layer is a first polar electrode layer, and the second contactless force action layer is a second polar electrode layer with a different polarity from that of said first polar electrode.

7. The image stabilization driving device of claim 6, wherein said first polar electrode layer and second polar electrode layer are a positive electrode layer and a negative electrode layer respectively with different polarities.

8. The image stabilization driving device of claim 1, wherein said flat SAW actuator further comprises a piezoelectric substrate and two pairs of Inter-digital Transducers orthogonally formed on a surface of said piezoelectric substrate.

9. The image stabilization driving device of claim 1 further comprises a position sensor for sensing a planar movement position of said slidable block.

10. The image stabilization driving device of claim 9, wherein said position sensor is selected from a group consisting of a self-magnetic sensor, a capacitive sensor and an optical sensor.

11. An image stabilization driving device for driving a planar movement of an image sensor, comprising:
a first slidable block coupled to said image sensor;
a first linear SAW actuator carrying and contacting with said slidable block to drive a planar movement of said slidable block on a surface contacted therewith; and
an contactless force action unit having a first contactless force action layer formed between said slidable block and said image sensor.
a second slidable block coupled to a bottom surface of said first SAW actuator;
a second linear SAW actuator being orthogonal to said first linear SAW actuator and carrying and contacting with said second slidable block to drive a linear movement of said second slidable block on a surface contacted therewith; and
an contactless force action unit, further comprising a first contactless force action layer formed between said first slidable block and said image sensor and between said second slidable block and said first SAW actuator respectively, and a second contactless force action layer formed on a bottom surface of said second SAW actuator, thereby providing a preload force for said first and second slidable blocks to contact with said first and second linear SAW actuators respectively by a mutually attracting force between said first and second contactless force action layers.

12. The image stabilization driving device of claim 11, wherein a surface of said first slidable block contacted with said first linear SAW actuator has a plurality of contact dots to reduce surface friction thereon.

13. The image stabilization driving device of claim 11, wherein a surface of said second slidable block contacted with said second linear SAW actuator has a plurality of contact dots to reduce surface friction thereon.

14. The image stabilization driving device of claim 12, wherein said plural contact dots are aligned in form of a matrix.

15. The image stabilization driving device of claim 11, wherein said first contactless force action layer is a permeable layer, and said second contactless force action layer is a permanent-magnet layer.

16. The image stabilization driving device of claim 15, wherein said permanent-magnet layer is a permanent-magnet substrate bonded to said bottom surface of said second linear SAW actuator.

17. The image stabilization driving device of claim 11, wherein said first contactless force action layer is a first polar electrode layer, and said contactless force action layer is a second polar electrode layer with a different polarity from that of said first polar electrode.

18. The image stabilization driving device of claim 17, wherein said first polar electrode layer and second polar electrode layer are a positive electrode layer and a negative electrode layer respectively with different polarities.

19. The image stabilization driving device of claim 11, wherein said first and second linear SAW actuators further comprise a piezoelectric substrate and two pairs of Inter-digital Transducers orthogonally formed on a surface of said piezoelectric substrate.

20. The image stabilization driving device of claim 11 further comprises a position sensor for sensing a planar movement position of said first slidable block.

21. The image stabilization driving device of claim 20, wherein said position sensor is selected from a group consisting of a self-magnetic sensor, a capacitive sensor and an optical sensor.
